(19) United States
(12) Patent Application Publication
(10) Pub. No.: US 2012/0080706 A1
(43) Pub. Date: Apr. 5, 2012

(54) CHIP PACKAGE AND METHOD FOR FORMING THE SAME

(76) Inventors: Ming-Kun YANG, Pingzhen City (TW); Tsang-Yu LIU, Zhubei City (TW)

(21) Appl. No.: 13/250,752

(22) Filed: Sep. 30, 2011

Related U.S. Application Data
(60) Provisional application No. 61/389,540, filed on Oct. 4, 2010.

(51) Int. Cl. H01L 33/60

(52) U.S. Cl. 257/98; 438/27; 257/774; 257/E33.062

(57) ABSTRACT

An embodiment of the invention provides a chip package which includes: a substrate having a surface; a reflective layer partially covering the surface of the substrate; an insulating layer formed on the surface of the substrate and the reflective layer; a conducting layer formed on the insulating layer, wherein at least a portion of a direct projection of the conducting layer on the surface does not overlap with a direct projection of the reflective layer on the surface, and the conducting layer does not electrically contact with the reflective layer; and a chip disposed on the surface of the chip, wherein the chip has at least an electrode electrically connected to the conducting layer.

### CROSS REFERENCE TO RELATED APPLICATIONS

This Application claims the benefit of U.S. Provisional Application No. 61/389,540, filed on Oct. 4, 2010, the entirety of which is incorporated by reference herein.

### BACKGROUND OF THE INVENTION

1. Field of the Invention

The present invention relates to a chip package, and in particular relates to a light emitting chip package.

2. Description of the Related Art

A chip package is used to protect a chip packaged therein and provide conducting routes for the chip and electronic elements outside of the chip package. For a light emitting chip package, it is also desired to enhance light emitting efficiency thereof.

Thus, a technology which can enhance the light emitting efficiency of the light emitting chip package is desired. It is also needed to ensure that high voltage operation is achievable for the light emitting chip package.

### BRIEF SUMMARY OF THE INVENTION

An embodiment of the invention provides a chip package which includes: a substrate having a surface; a reflective layer partially covering the surface of the substrate; an insulating layer formed on the surface of the substrate and the reflective layer; a conducting layer formed on the insulating layer, wherein at least a portion of a direct projection of the conducting layer on the surface does not overlap with a direct projection of the reflective layer on the surface, and the conducting layer does not electrically contact with the reflective layer; and a chip disposed on the surface of the substrate, wherein the chip has at least an electrode electrically connected to the conducting layer.

An embodiment of the invention provides a method for forming a chip package which includes: providing a substrate having a surface; forming a reflective layer on a portion of the surface of the substrate; forming an insulating layer on the surface of the substrate and the reflective layer; forming a conducting layer on the insulating layer, wherein at least a portion of a direct projection of the conducting layer on the surface does not overlap with a direct projection of the reflective layer on the surface, and the conducting layer does not electrically contact with the reflective layer; disposing a chip on the surface of the substrate, wherein the chip has at least an electrode; and electrically connecting the electrode to the conducting layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1F are cross-sectional views showing the steps of forming a chip package according to an embodiment of the present invention;

FIG. 2 is a cross-sectional view showing a chip package according to an embodiment of the present invention;

FIGS. 3A-3D are top views showing chip packages according to a plurality of embodiments of the present invention;

FIGS. 4A-4B are cross-sectional views showing the steps of forming a chip package according to an embodiment of the present invention; and

FIG. 5 is a three-dimensional view showing a chip package according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

A chip package according to an embodiment of the present invention may be used to package a light emitting element such as a light emitting diode chip. However, embodiments of the invention are not limited thereto. For example, the chip package of the embodiments of the invention may be applied to active or passive devices, or electronic components with digital or analog circuits, such as opto electronic devices, micro electro mechanical systems (MEMS), micro fluidic systems, and physical sensors for detecting heat, light, or pressure. Particularly, a wafer scale package (WSP) process may be applied to package semiconductor chips, such as image sensor devices, light-emitting diodes (LEDs), solar cells, RF circuits, accelerators, gyroscopes, micro actuators, surface acoustic wave devices, pressure sensors, ink printer heads, or power MOSFET modules.

The wafer scale package process mentioned above mainly means that after the package process is accomplished during the wafer stage, the wafer with chips is cut to obtain separate independent packages. However, in a specific embodiment, separate independent chips may be redistributed overlying a supporting wafer and then be packaged, which may also be referred to as a wafer scale package process. In addition, the above mentioned wafer scale package process may also be adapted to form chip packages of multi-layer integrated circuit devices by stacking a plurality of wafers having integrated circuits. In one embodiment, after the dicing process is performed, the obtained chip package is a chip scale package (CSP). The size of the chip scale package (CSP) may be only slightly larger than the size of the packaged chip. For example, the size of the chip scale package is not larger than 120% of the size of the packaged chip.

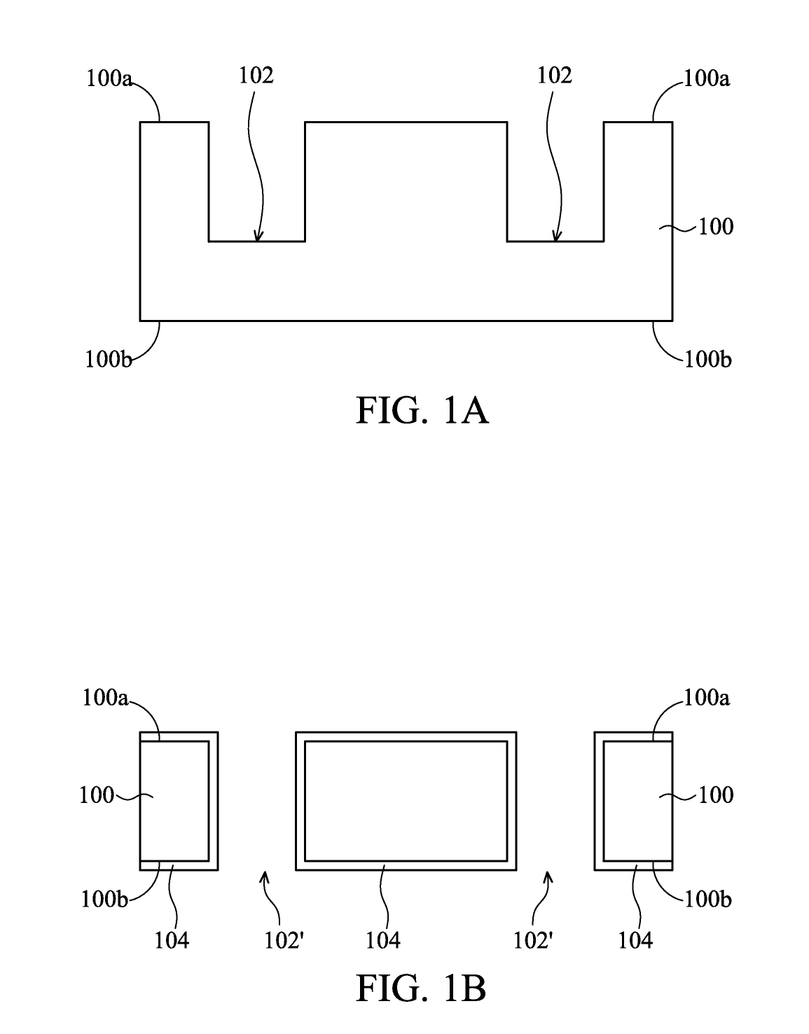

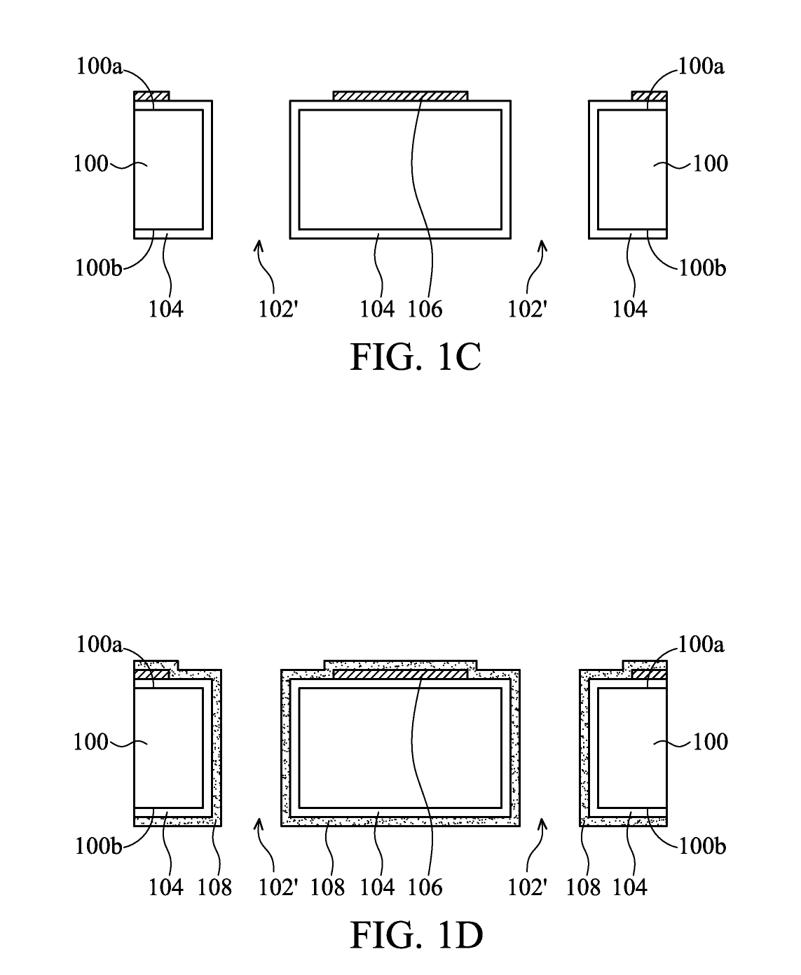

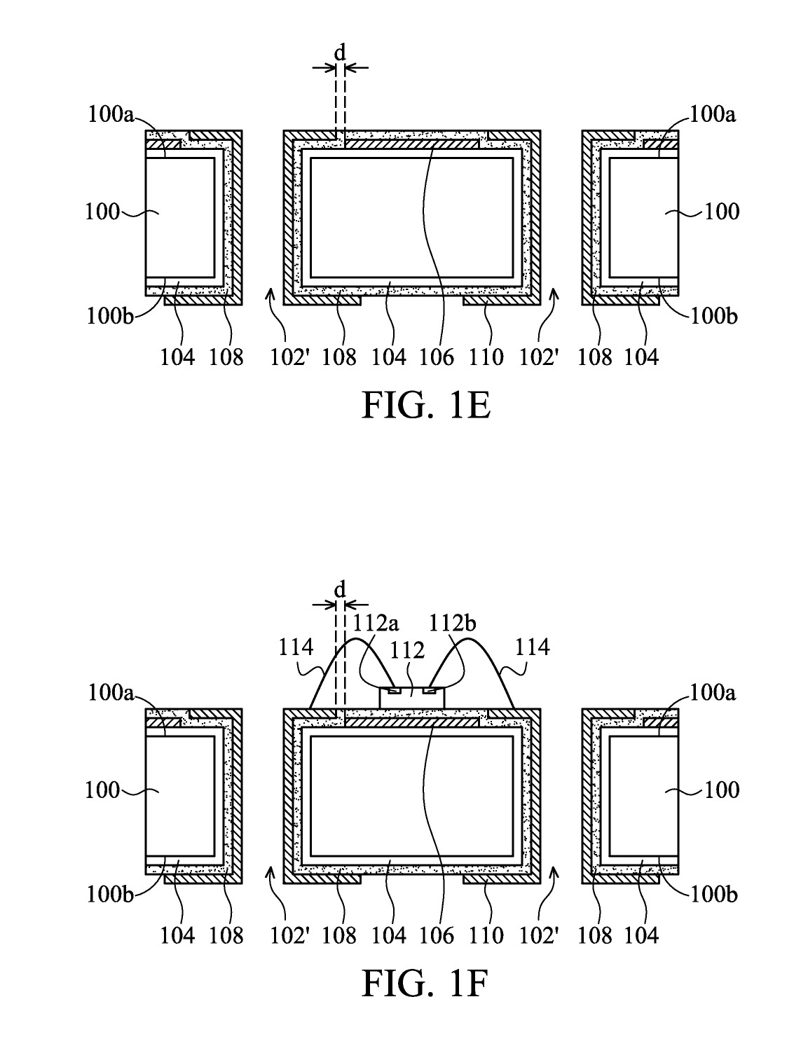

FIGS. 1A-1F are cross-sectional views showing the steps for forming a chip package according to an embodiment of the present invention. As shown in FIG. 1A, a substrate 100 is provided. In one embodiment, the substrate 100 is a semiconductor wafer (such as a silicon wafer), and a wafer-level packaging process may be performed to reduce fabrication time and cost. The substrate 100 has a surface 100a and a surface 100b. The surfaces 100a and 100b may be, for example, opposite to each other.

In one embodiment, a through substrate conducting structure may be optionally formed in the substrate 100 to electrically connect elements disposed on the two surfaces of the substrate 100. For example, a portion of the substrate 100 may be optionally removed from the surface 100a of the substrate 100 to form a hole 102 extending from the surface 100a towards the surface 100b. The hole 102 may be formed by using, for example, a photolithography process and an etching process.

Next, as shown in FIG. 1B, the substrate 100 may be thinned from the surface 100b of the substrate 100 to expose the hole 102, thus forming a through-hole 102′. The substrate 100 may be thinned to a suitable thickness according to requirements. Then, an insulating layer 104 may be optionally formed on the surface of the substrate 100 and the sidewall of the through-hole 102′. In one embodiment, the insulating layer 104 may be (but is not limited to) a thermal oxidation layer. For example, if the substrate 100 is a silicon wafer, the insulating layer 104 may be a silicon oxide layer formed on the surface of the silicon wafer by using a thermal oxidation process. The insulating layer 104 may also be formed by using another suitable manufacturing process and/or another suitable material.

As shown in FIG. 1C, a reflective layer 106 is then formed on a portion of the surface (such as the surface 100a) of the substrate 100. In one embodiment, a reflective material layer (not shown) may be formed on the surface of the substrate 100 by, for example, sputtering. The material of the reflective material layer may include, for example, (but is not limited to) aluminum, silver, gold, copper, alloy thereof, or combinations thereof. Then, the reflective material layer may be patterned to be the reflective layer 106 shown in FIG. 1C by using, for example, a photolithography process and an etching process.

Next, as shown in FIG. 1D, an insulating layer 108 is formed on the surface 100a of the substrate 100 and the reflective layer 106. In the embodiment shown in FIG. 1D, the insulating layer 108 further extends on the sidewall of the through-hole 102′ and extends on the surface 100b of the substrate 100. The material of the insulating layer 108 includes a polymer material such as epoxy resin, polyimide, or combinations thereof. The material of the insulating layer 108 may also include an oxide, nitride, oxynitride, metal oxide, or combinations thereof. The insulating layer 108 may be formed by using, for example, a spray coating process, printing process, dipping process, chemical vapor deposition process, or combinations thereof. In one embodiment, the insulating layer 108 may be a transparent insulating layer.

As shown in FIG. 1E, a conducting layer 110 is then formed on the insulating layer 108. The material of the conducting layer 110 may include, for example, (but is not limited to) copper, aluminum, gold, nickel, tungsten, alloy thereof, or combinations thereof. The fabrication method of the conducting layer 110 includes sputtering, evaporation, electroplating, and/or electroless plating. In the following description, an electroplating process is taken as an example to illustrate the formation process of the conducting layer 110.

In one embodiment, a seed layer (not shown) may be formed on the sidewall of the through-hole 102′ and the surfaces 100a and 100b of the substrate 100 by, for example, physical vapor deposition. Then, a patterned mask layer (not shown) is formed on the seed layer. The patterned mask layer has a plurality of openings, wherein the openings expose regions where the conducting layer 110 will be actually formed. Then, a conducting material may be electroplated on the exposed seed layer by using an electroplating process. Then, the patterned mask layer is removed, and an etching process is applied to the seed layer thereunder. By using the method mentioned above, the conducting layer 110 having desired conducting patterns is formed on the surfaces 100a and 100b of the substrate 100. The conducting layer 110 may extend into the through-hole 102′ and extend on the surfaces 100a and 100b, thus electrically connecting to elements located on opposite surfaces of the substrate 100.

In one embodiment, at least a portion of a direct projection of the conducting layer 110 on the surface 100a does not overlap with a direct projection of the reflective layer 106 on the surface 100a, and the conducting layer 110 does not electrically contact with the reflective layer 106. A patterning process of the conducting layer 110 may be applied to achieve the disposition relationship between the conducting layer 110 and the reflective layer 106 mentioned above. For example, in the embodiment shown in FIG. 1E, the direct projection of the conducting layer 110 on the surface 100a completely does not overlap with the direct projection of the reflective layer 106 on the surface 100a. Thus, a side of the conducting layer 110 is separated from a side of the reflective layer 106 by a minimum lateral distance d. In addition, in order to prevent short circuiting from occurring between the conducting layer 110 and the reflective layer 106 to affect operation of the formed chip package, the conducting layer 110 needs to not electrically contact with the reflective layer 106. For example, in the embodiment shown in FIG. 1E, the conducting layer 110 is separated from the reflective layer 106 by at least the insulating layer 108, without directly contacting with each other.

Next, as shown in FIG. 1F, a chip 112 is disposed on the surface 100a of the substrate 100. The chip 112 may include a light emitting element. For example, the chip 112 may be a light emitting diode chip. The chip 112 has at least an electrode used for receiving and/or transporting electrical signals. For example, if the chip 112 is a light emitting diode chip, the chip 112 may include an electrode 112a and an electrode 112b. In addition, although both the electrode 112a and the electrode 112b of the chip 112 are located on the upper surface of the chip 112 in the embodiment shown in FIG. 1F, embodiments of the invention are not limited thereto. In another embodiment, both the electrode 112a and the electrode 112b of the chip 112 may be located on the lower surface of the chip 112. Alternatively, the electrode 112a and the electrode 112b of the chip 112 may be located on opposite surfaces of the chip 112, respectively. If the substrate 100 is a silicon wafer, a dicing process may be subsequently performed to form a plurality of separate chip packages.

As shown in FIG. 1F, the electrode (such as the electrode 112a) of the chip 112 is then electrically connected to the conducting layer 110. For example, a bonding wire 114 may be formed between the electrode of the chip 112 and the conducting layer 110. Alternatively, in another embodiment, a redistribution layer may be used to form the electrical connection between the electrode of the chip 112 and the conducting layer 110. In addition, another electrode (such as the electrode 112b) of the chip 112 may be electrically connected to another conducting layer (such as a conducting layer in another through-hole). The step of electrically connecting the electrode (such as the electrode 112a) of the chip 112 and the conducting layer 110 is not limited to be performed after the dicing process. In some embodiments, after the electrical connection between the chip 112 and the conducting layer 110 is formed, the dicing process is then performed to form a plurality of separate chip packages.

As shown in FIG. 1F, because the reflective layer 106 is disposed on nearby regions under the chip 112, a portion of the emitted light of the chip 112 (if the chip 112 is a light emitting chip) may be reflected by the reflective layer 106 to travel along a specific direction. Thus, illumination intensity of the chip package may be improved. Further, because at least a portion of the direct projection of the conducting layer 110 on the surface 100a does not overlap with the direct projection of the reflective layer 106 on the surface 100a, it is not easy for breakdown to occur between the conducting layer 110 and the reflective layer 106 due to high voltage operation or high current operation.

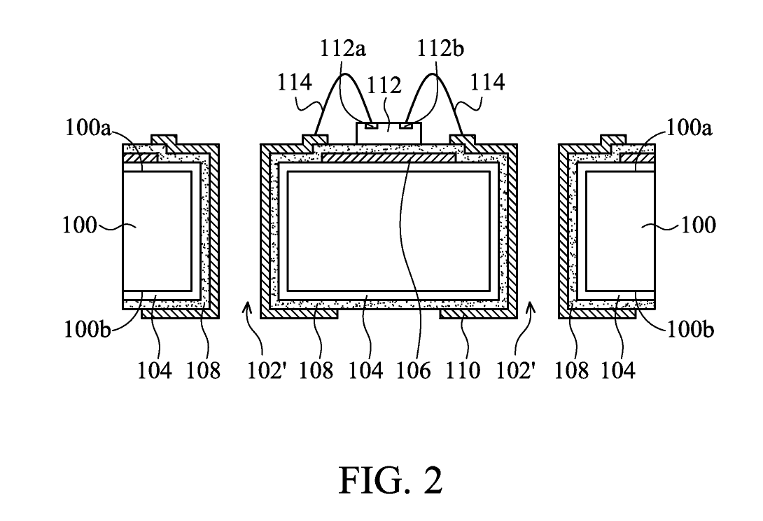

In the chip package of the embodiment of the invention, the direct projection of the conducting layer 110 on the surface 100a completely does not overlap with the direct projection of the reflective layer 106 on the surface 100a to prevent short circuiting from occurring between the conducting layer 110 and the reflective layer 106. However, embodiments of the invention are not limited thereto. FIG. 2 is a cross-sectional view showing a chip package according to an embodiment of the present invention, wherein same or similar reference numbers are used to designate same or similar elements. In the embodiment shown in FIG. 2, the conducting layer 110 partially overlaps with the reflective layer 106. However, because the range of the overlapped portion is not big, short circuiting can still be prevented from occurring between the conducting layer 110 and the reflective layer 106.

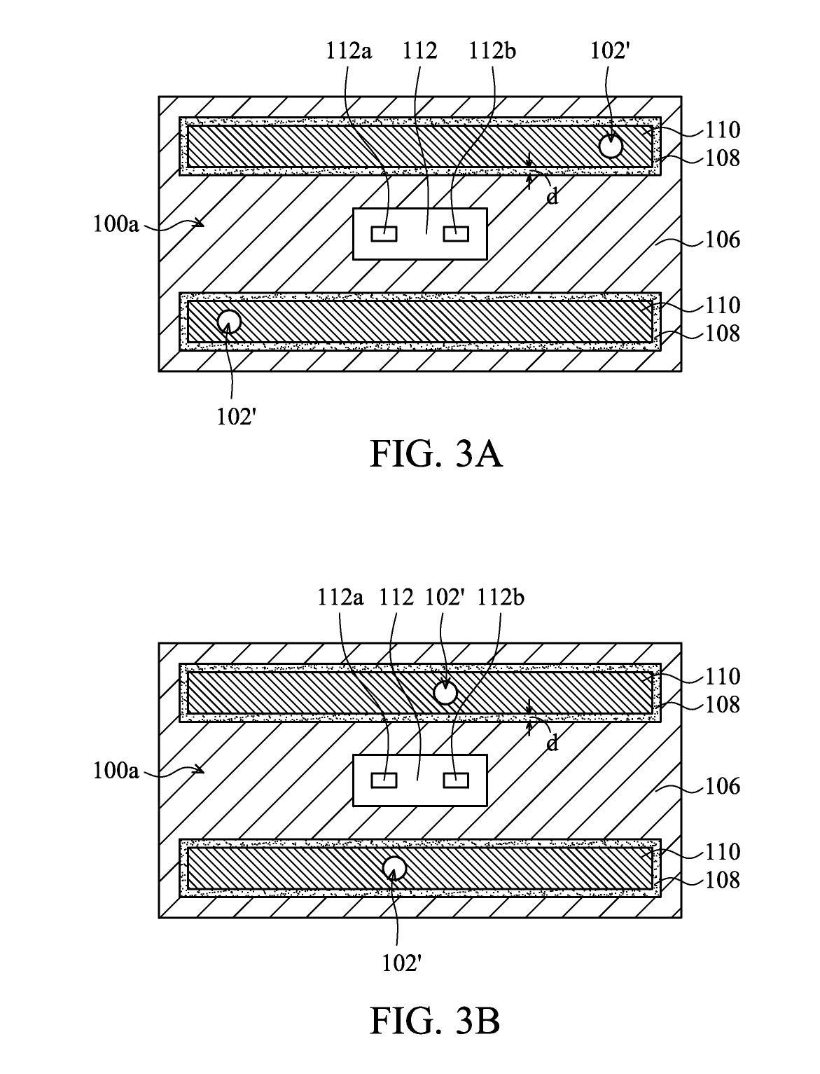

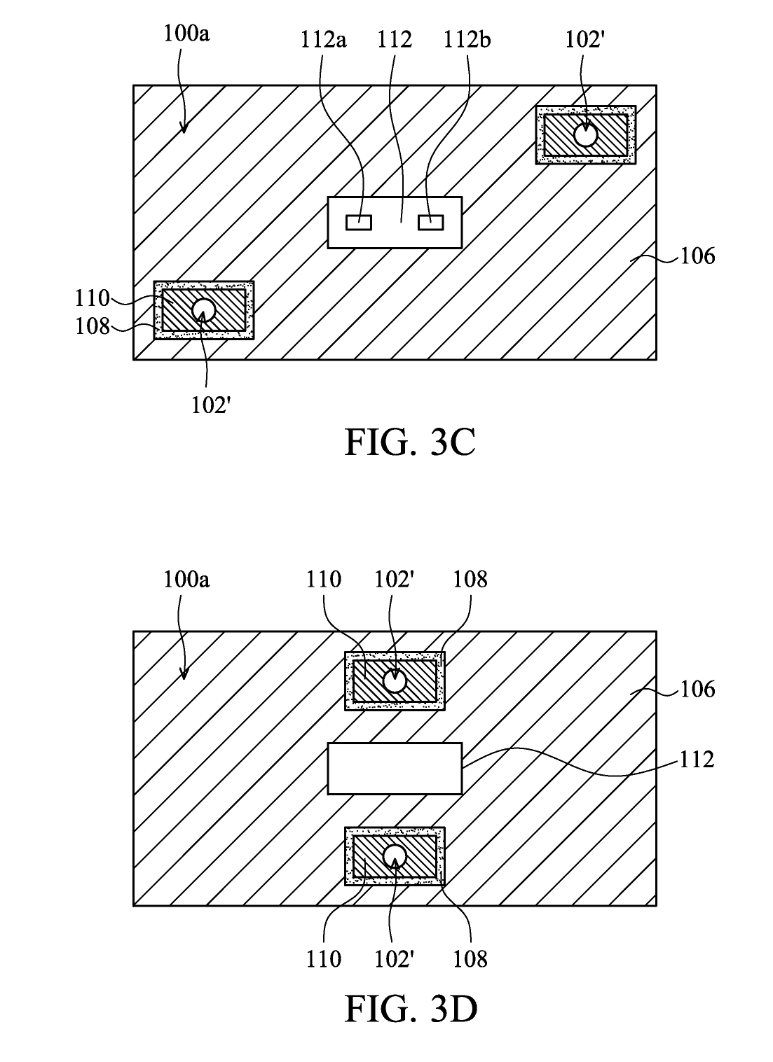

FIGS. 3A-3D are top views (observed from the surface 100a) showing chip packages according to a plurality of embodiments of the present invention, wherein same or similar reference numbers are used to designate same or similar elements. As shown in FIG. 3A, in this embodiment, both the reflective layer 106 and the conducting layer 110 are specifically patterned such that at least a portion of the direct projection of the conducting layer 110 on the surface 100a does not overlap with the direct projection of the reflective layer 106 on the surface 100a. In this embodiment, the direct projection of the conducting layer 110 on the surface 100a completely does not overlap with the direct projection of the reflective layer 106 on the surface 100a such that the side of the conducting layer 110 and the side of the reflective layer 106 are separated from each other by a minimum distance d. Thus, when a high current flows to the chip 112 through the electrode 112a and the electrode 112b, short circuiting does not occur between the current in the conducting layer 110 and the reflective layer 106 such that the chip package can not operate. In addition, as shown in FIG. 3A, the conducting layer 110 may extend into the through-hole 102′ and further extend on the opposite surface (102b, not shown). In one embodiment, an area of the direct projection of the reflective layer 106 on the surface 100a is larger than an area of the direct projection of the conducting layer 110 on the surface 100a. Thus, the amount of the reflected light is more sufficient such that light emitting efficiency of the chip package may be improved.

In addition, it should be appreciated that the location of the through-hole 102′ is not limited to be that shown in the embodiment in FIG. 3A where the through-hole 102′ is located at the corner. In another embodiment, in the fabrication process of the through-hole 102′, the through-hole 102′ may be located at another suitable location. As shown in the embodiment in FIG. 3B, the location of the through-hole 102′ may be adjusted to be at a center of the chip package.

The occupation area of the conducting layer 110 on the surface 100a may be further reduced to increase the occupation area of the reflective layer 106 such as that shown in the embodiment in FIG. 3C. Similarly, locations of the conducting layer 110 and the through-hole 102′ may also be adjusted according to the situation such as that shown in the embodiment in FIG. 3D.

In the embodiments mentioned above, the through substrate conducting structure of the chip package is formed in the through-hole 102′ and surrounded by the substrate 100. However, embodiments of the invention are not limited thereto. In another embodiment, the through substrate conducting structure may be exposed on a side surface of the substrate 100 and serve as a side electrode.

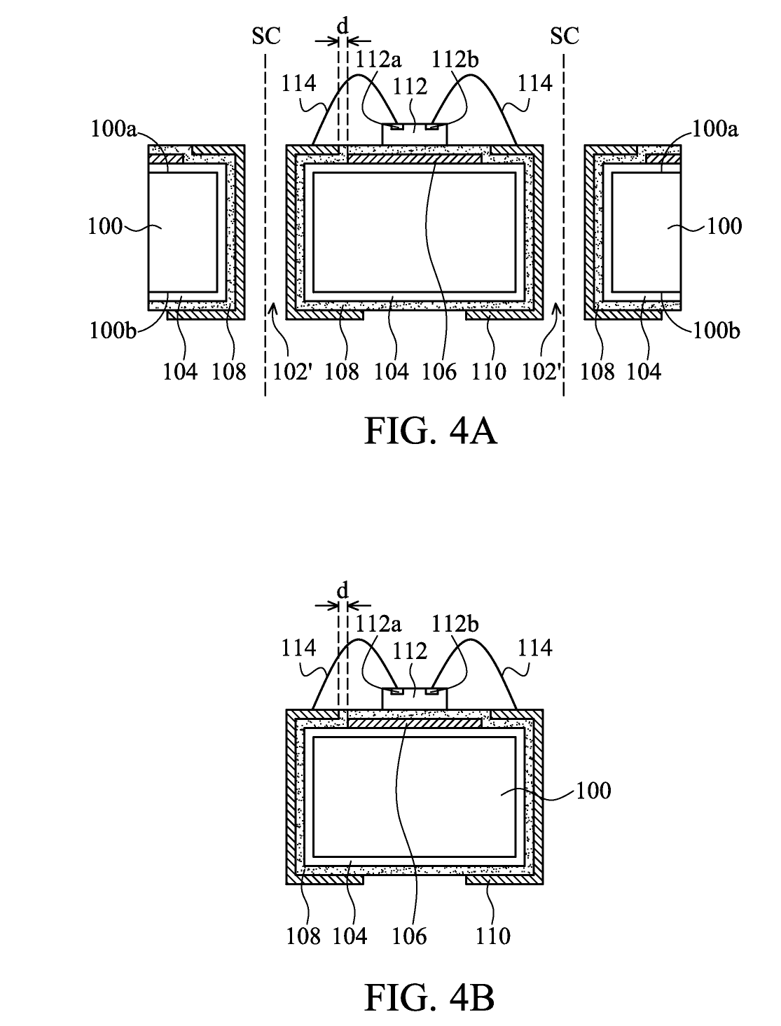

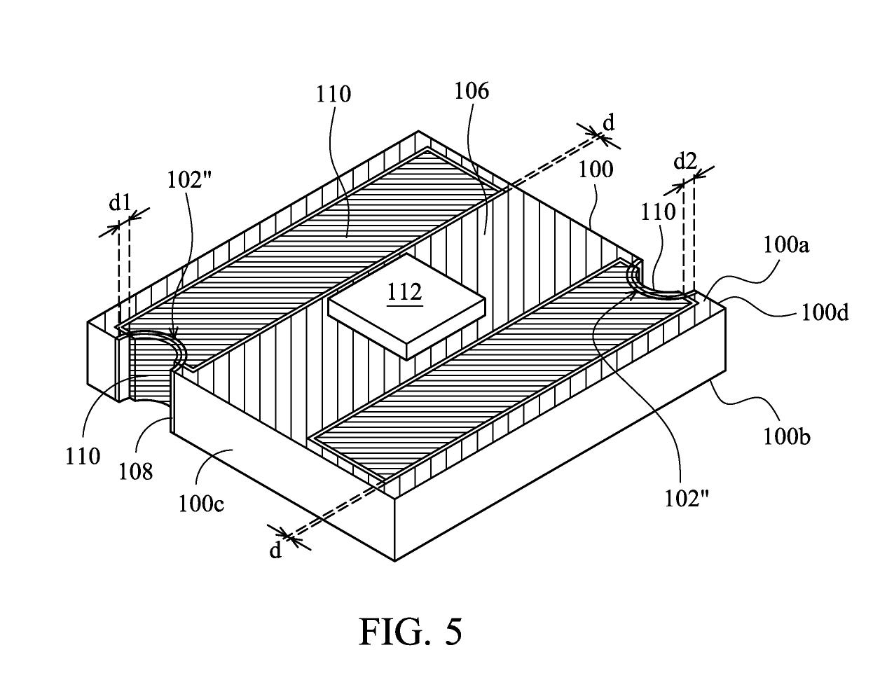

FIGS. 4A-4B are cross-sectional views showing the steps of forming a chip package according to an embodiment of the present invention. As shown in FIG. 4A, by using a method similar to that illustrated in FIGS. 1A-1F, a plurality of chips, reflective layers, and through substrate conducting structures are disposed on the substrate 100 (such as a wafer). Compared with the embodiments mentioned above, the main difference is that the predetermined scribe line SC defined on the substrate 100 penetrates through the through-hole 102′ formed in the substrate 100.

Next, as shown in FIG. 4B, the substrate 100 is diced along the predetermined scribe line SC to form a plurality of chip packages. FIG. 5 is a three-dimensional view showing the chip package corresponding to that shown in FIG. 4B. As shown in FIG. 5, because the chip 100 is diced along the scribe line SC penetrating through the through-hole 102′, the through substrate conducting structure is exposed on the sidewall of the substrate 100 of the obtained chip package and thus becomes a side electrode of the chip package.

As shown in FIG. 5, the chip package includes a trench 102″ (i.e., a portion of the through-hole 102′ exposed after the dicing process) extending from the surface 100a towards the surface 100b of the substrate 100 and extending from a side surface 100c of the substrate towards an inner portion of the substrate 100. The conducting layer 110 is located on the sidewall of the trench 102″. It is preferable that the conducting layer 110 is not coplanar with the side surface 100c of the substrate 100 and is separated from the side surface 100c by a minimum distance d1. The conducting layer 110 located in the trench 102″ may serve as a side electrode of the chip package. In one embodiment, before the dicing process is performed, the conducting layer 110 in the through-hole 102′ may be patterned to remove the conducting layer 110 near the predetermined scribe line SC. Thus, when the dicing process is performed, the dicing blade does not contact with the conducting layer 110 to ensure that the conducting layer 110 is not removed or damaged due to the dicing process. Thus, in the embodiment shown in FIG. 5, the conducting layer 110 is not coplanar with the side surface 100c of the substrate 100 and is separated from the side surface 100c by a minimum distance d1.

In addition, the chip package may include more side electrodes, wherein the side electrodes may be located on any side surface of the substrate of the chip package according to requirements. For example, in the embodiment shown in FIG. 5, the chip package further includes trenches 102″ (i.e., a portion of the through-hole 102′ exposed after the dicing process) extending from the surface 100a towards the surface 100b of the substrate 100 and extending from a side surface 100d towards an inner portion of the substrate 100. The conducting layer 110 is located on the sidewall of the trench 102″. It is preferable that the conducting layer 110 is not coplanar with the side surface 100d of the substrate and is separated from the side surface 100d by a minimum distance d2. The conducting layer 110 located in the trench 102″ (right) may serve as another side electrode of the chip package.

In one embodiment, the chip 112 disposed on the reflective layer 106 on the substrate 100 may be a light emitting chip and have at least two electrodes. One of the electrodes of the light emitting chip may be electrically connected to the side electrode on the side surface 100c through a redistribution layer or a bonding wire. Similarly, another electrode of the light emitting chip may also be electrically connected to the side electrode on the side surface 100d through a redistribution layer or a bonding wire.

In addition, for the convenience of the formation of a subsequently formed conducting structure (such as a bonding wire), the conducting layer 110 may further extend on the surface of the substrate 100. As shown in FIG. 5, in one embodiment, the layout may be similar to that shown in the embodiment in FIG. 3A, on the surface of the chip package having side electrodes. The embodiment in FIG. 5 may be diced from the substrate along a Y direction (longitudinal direction).

It should be appreciated that embodiments of the invention are not limited thereto. For example, in another embodiment, the layout may be similar to (but is not limited to) that shown in the embodiment in FIG. 3B or FIG. 3C, on the surface of the chip package having side electrodes. The layout may depend on requirements. For example, if a bonding wire is used to form an external conducting route of the chip package, it is preferable to have a conducting layer layout which has a sufficient area for facilitating a subsequent wire bonding process.

In the embodiments of the invention, a reflective layer is used to improve light emitting efficiency of the chip package. In addition, through the design of the layout of the reflective layer and the conducting layer, short circuiting between the conducting layer and the reflective layer may be significantly prevented. Thus, the chip package may be adopted in applications using high voltage and high current.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a substrate having a surface;
a reflective layer partially covering the surface of the substrate;
an insulating layer formed on the surface of the substrate and the reflective layer;
a conducting layer formed on the insulating layer, wherein at least a portion of a direct projection of the conducting layer on the surface does not overlap with a direct projection of the reflective layer on the surface, and the conducting layer does not electrically contact with the reflective layer; and
a chip disposed on the surface of the substrate, wherein the chip has at least an electrode electrically connected to the conducting layer.

2. The chip package as claimed in claim 1, wherein the direct projection of the conducting layer on the surface completely does not overlap with the direct projection of the reflective layer on the surface.

3. The chip package as claimed in claim 1, further comprising a second insulating layer between the substrate and the reflective layer.

4. The chip package as claimed in claim 1, further comprising a through-hole extending from the surface towards a second surface of the substrate.

5. The chip package as claimed in claim 4, wherein the conducting layer extends into the through-hole and extends on the second surface.

6. The chip package as claimed in claim 1, wherein the chip comprises a light emitting element.

7. The chip package as claimed in claim 1, wherein an area of the direct projection of the reflective layer on the surface is larger than an area of the direct projection of the conducting layer on the surface.

8. The chip package as claimed in claim 1, wherein the insulating layer is a transparent insulating layer.

9. The chip package as claimed in claim 1, wherein the electrode of the chip is electrically connected to the conducting layer through a bonding wire.

10. The chip package as claimed in claim 1, wherein the conducting layer does not directly contact with the reflective layer.

11. The chip package as claimed in claim 1, further comprising at least a trench extending from the surface towards a second surface of the substrate and extending from one side surface of the substrate towards an inner portion of the substrate, wherein the conducting layer extends on a sidewall of the trench.

12. The chip package as claimed in claim 11, wherein the conducting layer in the trench is not coplanar with the side surface and is separated from the side surface by a minimum distance.

13. A method for forming a chip package, comprising:
providing a substrate having a surface;
forming a reflective layer on a portion of the surface of the substrate;
forming an insulating layer on the surface of the substrate and the reflective layer;
forming a conducting layer on the insulating layer, wherein at least a portion of a direct projection of the conducting layer on the surface does not overlap with a direct projection of the reflective layer on the surface, and the conducting layer does not electrically contact with the reflective layer;
disposing a chip on the surface of the substrate, wherein the chip has at least an electrode; and
electrically connecting the electrode to the conducting layer.

14. The method for forming a chip package as claimed in claim 13, wherein the direct projection of the conducting layer on the surface completely does not overlap with the direct projection of the reflective layer on the surface.

15. The method for forming a chip package as claimed in claim 13, further comprising forming a second insulating layer on the surface of the substrate before the reflective layer is formed.

16. The method for forming a chip package as claimed in claim 13, further comprising partially removing the substrate to form a through-hole before the reflective layer is formed, wherein the through-hole extends from the surface towards a second surface of the substrate.

17. The method for forming a chip package as claimed in claim 16, wherein the conducting layer extends into the through-hole and extends on the second surface.

18. The method for forming a chip package as claimed in claim 13, wherein the chip comprises a light emitting element.

19. The method for forming a chip package as claimed in claim 13, wherein an area of the direct projection of the reflective layer on the surface is larger than an area of the direct projection of the conducting layer on the surface.

20. The method for forming a chip package as claimed in claim 13, wherein the insulating layer is a transparent insulating layer.
